(19) United States
(12) Patent Application Publication
(10) Pub. No.: US 2024/0316571 A1
(43) Pub. Date: Sep. 26, 2024

(54) SUBSTRATE TREATING APPARATUS AND METHOD OF TREATING SUBSTRATE USING THE SAME

(71) Applicant: Samsung Display Co., Ltd., Yongin-si (KR)

(72) Inventors: YOUNG-HUN PARK, Yongin-si (KR); EUGENE KANG, Yongin-si (KR); CHANGWOOK SEO, Yongin-si (KR); SEUNG GEUN YUN, Yongin-si (KR)

(21) Appl. No.: 18/517,852

(22) Filed: Nov. 22, 2023

(30) Foreign Application Priority Data
Mar. 24, 2023 (KR) 10-2023-0038938

(51) Int. Cl. B03C 1/06; B03C 1/033

(52) U.S. Cl. CPC B03C 1/06; B03C 1/0332

(57) ABSTRACT

A substrate treating apparatus includes a chamber defining a chamber cavity, a substrate carrier movable in a first direction inside of the chamber cavity, and a filter disposed inside the chamber cavity, defining an opening through which the substrate carrier passes, and including a magnet filter disposed in the opening and being rotatable.

This application claims priority to Korean Patent Application No. 10-2023-0038938, filed on Mar. 24, 2023, and all the benefits accruing therefrom under 35 USC § 119, the content of which in its entirety is herein incorporated by reference.

### BACKGROUND

### 1. Field

This invention relates to a substrate treating apparatus, and more particularly, to a substrate treating apparatus and a method of treating a substrate using the same.

### 2. Description of the Related Art

As information technology develops, the importance of display devices, which are a communication media between users and information, is being highlighted. Accordingly, display devices such as liquid crystal display devices, organic light emitting display devices, plasma display devices, or the like are widely used in various fields.

The display device may be manufactured through processes where each step of the process is performed in a process chamber. In this case, a carrier may be used to transfer a substrate of the display device to each process chamber. The carrier may transfer the substrate to each chamber or transfer the substrate within the chamber.

### SUMMARY

Embodiments provide a substrate treating apparatus with improved efficiency.

Embodiments provide a method of treating a substrate using the substrate treating apparatus.

A substrate treating apparatus according to an embodiment includes a chamber, a substrate carrier movable in a first direction inside the chamber, and a filter disposed inside the chamber, defining an opening through which the substrate carrier passes, and including a magnet filter disposed in the opening and rotatable.

In an embodiment, the magnet filter may extend in a second direction intersecting the first direction, and may have a polygonal column shape including n side surfaces, where n is a natural number that is equal to or greater than three.

In an embodiment, the magnet filter may be rotatable by 360/n° around an axis that is in a direction that is parallel to the second direction.

In an embodiment, the filter may include a gear disposed at both ends of the magnet filter, respectively.

In an embodiment, the magnet filter may include a first magnet forming an outer surface.

In an embodiment, the first magnet may include a south pole and a north pole alternately arranged.

In an embodiment, the substrate carrier may include a second magnet disposed on one surface that is adjacent to the magnet filter.

In an embodiment, the second magnet may include a south pole and a north pole alternately arranged.

In an embodiment, the magnet filter may be rotatable by a magnetic force between the first magnet and the second magnet.

A method of treating a substrate, according to an embodiment, wherein the method includes inserting a substrate carrier into a chamber, passing the substrate carrier through an opening defined in a filter disposed inside the chamber, and rotating a magnet filter disposed in the opening.

In an embodiment, the magnet filter may extend in one direction, and may have a polygonal column shape including n side surfaces, where n is a natural number that is equal to or greater than three.

In an embodiment, in the rotating of the magnet filter, the magnet filter may be rotatable by 360/n° around an axis that is directed parallel to the one direction.

In an embodiment, in the passing of the substrate carrier through the opening of the filter, the magnet filter may collect metal foreign substances on the substrate carrier.

In an embodiment, in the rotating of the magnet filter, an inside of the chamber may be maintained in a vacuum state.

In an embodiment, the magnet filter may include a first magnet forming an outer surface.

In an embodiment, the substrate carrier may include a second magnet disposed on one surface that is adjacent to the magnet filter.

In an embodiment, each of the first magnet and the second magnet may include a south pole and a north pole alternately arranged.

In an embodiment, in the rotating of the magnet filter, the magnet filter may be rotatable by a magnetic force between the first magnet and the second magnet.

In an embodiment, in the rotating of the magnet filter, an inside of the chamber may be maintained at an atmospheric pressure state.

In an embodiment, the filter may include a gear disposed at both ends of the magnet filter, respectively.

In a substrate treating apparatus according to embodiments, a magnet filter may have a polygonal column shape including n (where n is a natural number equal to or greater than three) side surfaces, and may be rotatable. As the magnet filter is rotated, the magnet filter may collect metal foreign substances generated in a process using each side surface. Accordingly, an ability of the magnet filter to collect metal foreign substances may be increased, and a cleaning cycle of the magnet filter may be relatively long.

In addition, as the magnet filter may be rotated by a magnetic force between a magnet of the magnet filter and a magnet of a substrate carrier, a chamber may be maintained in a vacuum state. That is, since conversion of an internal state of the chamber is not required, process efficiency may be improved.

### BRIEF DESCRIPTION OF THE DRAWINGS

FIG. 1 is a cross-sectional view illustrating a substrate treating apparatus, according to an embodiment.

FIG. 2 is a perspective view illustrating the substrate treating apparatus of FIG. 1.

FIG. 3 is a perspective view illustrating a magnet filter and a gear included in the substrate treating apparatus of FIG. 1, according to an embodiment.

FIG. 4 is a perspective view illustrating a magnet filter and a gear included in the substrate treating apparatus of FIG. 1, according to another embodiment.

FIG. 5 is a perspective view illustrating a magnet filter and a gear included in the substrate treating apparatus of FIG. 1, according to still another embodiment.

FIG. 6 is a perspective view illustrating a magnet filter and a gear included in the substrate treating apparatus of FIG. 1, according to still another embodiment.

FIG. 7 is a perspective view illustrating the substrate treating apparatus of FIG. 1, according to another embodiment.

### DETAILED DESCRIPTION OF THE EMBODIMENTS

Hereinafter, embodiments of the invention will be described in more detail with reference to the accompanying drawings. The same reference numerals are used for the same components in the drawings, and redundant descriptions of the same components will be omitted.

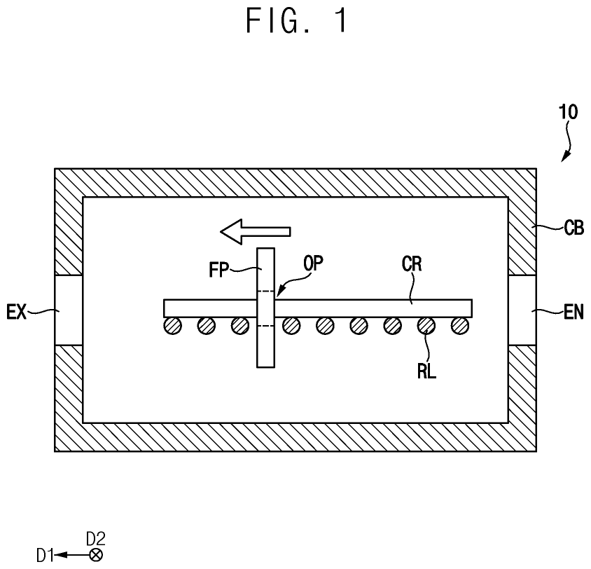

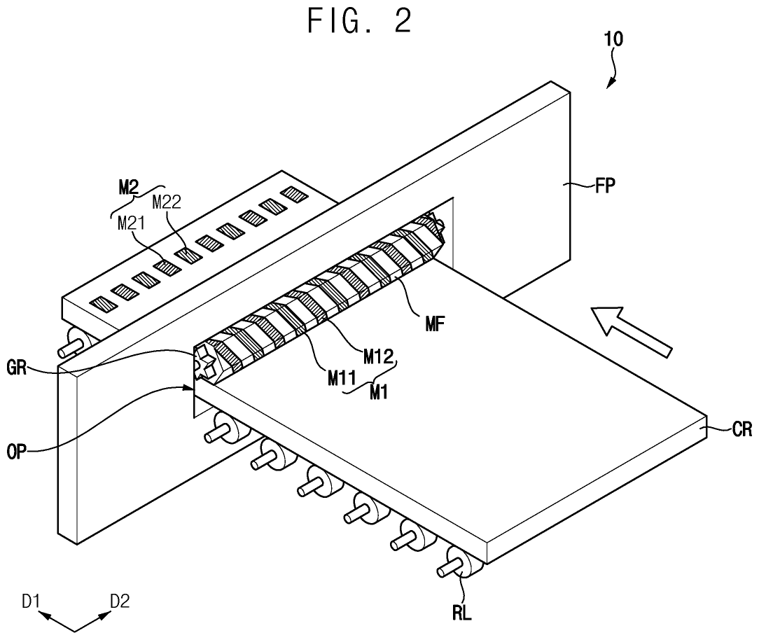

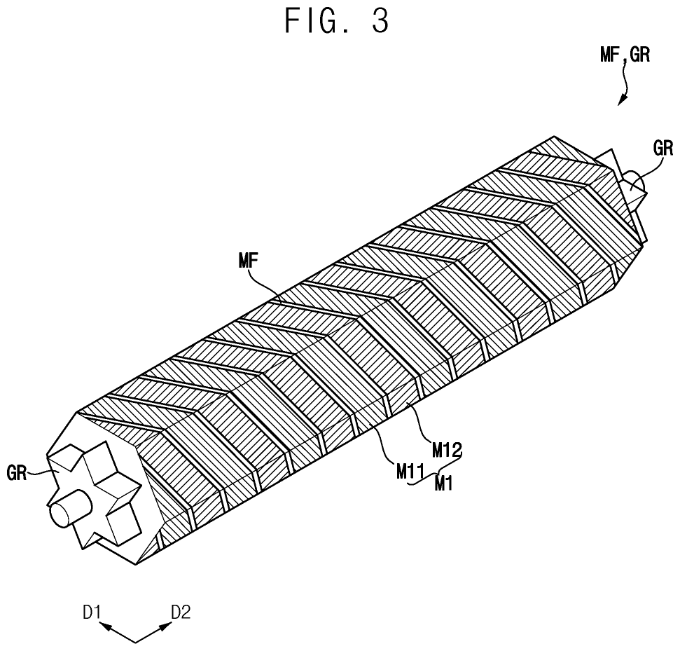

FIG. 1 is a cross-sectional view illustrating a substrate treating apparatus, according to an embodiment. FIG. 2 is a perspective view illustrating the substrate treating apparatus of FIG. 1. FIG. 3 is a perspective view illustrating a magnet filter and a gear included in the substrate treating apparatus of FIG. 1, according to an embodiment.

In an embodiment and referring to FIGS. 1, 2 and 3, a substrate treating apparatus 10 may include a chamber CB, a filter FP, a substrate carrier CR and a plurality of transfer rollers RL.

In an embodiment, the chamber CB may include an empty space therein. Specifically, the chamber CB may define a space in which a process of treating a target substrate is performed. An inside of the chamber CB may be maintained in a vacuum state or an atmospheric pressure state.

In an embodiment, the chamber CB may include an inlet port EN into which the substrate carrier CR is inserted and an outlet port EX through which the substrate carrier CR is taken out. The inlet port EN may be formed on one side of the chamber CB, and the outlet port EX may be formed on the other side of the chamber CB. Accordingly, the substrate carrier CR may be inserted into the chamber CB through the inlet port EN, and the substrate carrier CR may be taken out of the chamber CB through the outlet port EX.

In an embodiment, the filter FP may be disposed inside the chamber CB. The substrate carrier CR may pass through the filter FP along a first direction D1. The filter FP may define an opening OP. The opening OP may extend in a second direction D2 intersecting the first direction D1. For example, the first direction D1 and the second direction D2 may be perpendicular to each other. The substrate carrier CR may pass through the filter FP through the opening OP.

In an embodiment, the filter FP may include a magnet filter MF and a gear GR.

In an embodiment, the magnet filter MF may be disposed in the opening OP. The magnet filter MF may collect metal foreign substances on the substrate carrier CR that passes through the opening OP. That is, the magnet filter MF may collect metal foreign substances generated in the process of treating the target substrate.

In an embodiment, the magnet filter MF may extend in the second direction D2. In an embodiment, the magnet filter MF may have a polygonal column shape including n side surfaces, where n is a natural number that is equal to or greater than three. For example, the magnet filter MF may have a hexagonal column shape including six side surfaces (see FIG. 3).

In an embodiment, the magnet filter MF may include a first magnet M1. The first magnet M1 may form an outer surface of the magnet filter MF. The first magnet M1 may include a first first magnet M11 (hereinafter, referred to as “(1-1)th magnet”) and a second first magnet M12 (hereinafter, referred to as “(1-2)th magnet”). The (1-1)th magnet M11 and the (1-2)th magnet M12 may have different polarities. For example, the (1-1)th magnet M11 may have a north pole, and the (1-2)th magnet M12 may have a south pole. As another example, the (1-1)th magnet M11 may have a south pole, and the (1-2)th magnet M12 may have a north pole. The (1-1)th magnet M11 and the (1-2)th magnet M12 may have a spiral shape, and be alternately arranged. That is, each of the (1-1)th magnet M11 and the (1-2)th magnet M12 may have a spiral shape surrounding the outer surface of the magnet filter MF.

In an embodiment, the magnet filter MF may be rotatable. In an embodiment, the magnet filter MF may be rotatable by one side surface around an axis parallel to the second direction D2. In other words, the magnet filter MF may be rotatable by 360/n° around the axis parallel to the second direction D2. For example, when the magnet filter MF includes six side surfaces, the magnet filter MF may be rotatable by 60°.

In an embodiment, the gear GR may be disposed at both ends of the magnet filter MF, respectively. The gear GR may include the same number of teeth as the number of side surfaces included in the magnet filter MF. That is, when the magnet filter MF includes n side surfaces, the gear GR may include n teeth. For example, when the magnet filter MF includes six side surfaces, the gear GR may include six teeth (see FIG. 3). Accordingly, the gear GR may allow the magnet filter MF to rotate one side surface at a time. That is, since the gear GR includes n teeth, the magnet filter MF including n side surfaces may be rotatable from one side surface to another side surface which is disposed adjacent to the one side surface.

In an embodiment, the substrate carrier CR may be parallel to a plane defined by the first direction D1 and the second direction D2. The substrate carrier CR may be coupled to the target substrate. The substrate carrier CR may be movable in the first direction D1 inside the chamber CB. That is, the substrate carrier CR may move the target substrate inside the chamber CB.

In an embodiment, the substrate carrier CR may include a second magnet M2 disposed on one surface. For example, the second magnet M2 may be disposed on one surface disposed adjacent to the magnet filter MF of the substrate carrier CR. In addition, the second magnet M2 may be disposed at one end of the substrate carrier CR that first passes through the opening OP.

In an embodiment, the second magnet M2 may include a first second magnet M21 (hereinafter, will be referred to as “(2-1)th magnet”) and a second second magnet M22 (hereinafter, will be referred to as “(2-2)th magnet”). The (2-1)th magnet M21 and the (2-2)th magnet M22 may have different polarities. For example, the (2-1)th magnet M21 may have a south pole, and the (2-2)th magnet M22 may have a north pole. For another example, the (2-1)th magnet M21 may have a south pole, and the (2-2)th magnet M22 may have a south pole.

In an embodiment, the (2-1)th magnet M21 and the (2-2)th magnet M22 may be alternately disposed along the second direction D2. Specifically, when the one end of the substrate carrier CR passes through the opening OP, the (2-1)th magnet M21 may be disposed adjacent to the (1-1)th magnet M11, and the (2-2)th magnet M22 may be disposed adjacent to the (1-2)th magnet M12.

In an embodiment, the (1-1)th magnet M11 and the (2-1)th magnet M21 may have different polarities. In addition, the (1-2)th magnet M12 and the (2-2)th magnet M22 may have different polarities. Accordingly, the magnet filter MF may be rotatable by a magnetic force between the first magnet M1 and the second magnet M2. Specifically, when the one end of the substrate carrier CR passes through the opening OP, the magnet filter MF may be rotatable by an attractive force between the (1-1)th magnet M11 and the (2-1)th magnet M21 and an attractive force between the (1-2)th magnet M12 and the (2-2)th magnet M22. That is, while the substrate carrier CR passes near the magnet filter MF, an attractive force may be generated between the first magnet M1 and the second magnet M2, and the magnetic filter MF may be rotated by 360/n° by the attractive force. In this case, since the magnet filter MF may be rotated by the magnetic force between the first magnet M1 and the second magnet M2, the inside of the chamber CB may be maintained in a vacuum state while the magnet filter MF is rotated. That is, it may not be necessary to convert an internal state of the chamber CB to rotate the magnet filter MF.

Although FIG. 2 illustrates that the magnet filter MF is disposed at an upper part of the opening OP, and is disposed above the substrate carrier CR passing through the opening OP, the invention is not limited thereto. Alternatively, in an embodiment, the magnet filter MF may be disposed at a lower part of the opening OP, and may be disposed below the substrate carrier CR passing through the opening OP.

In an embodiment, the transfer rollers RL may be arranged in the first direction D1 inside the chamber CB. The substrate carrier CR may be disposed on the transfer rollers RL. The transfer rollers RL may guide a movement of the substrate carrier CR. That is, the transfer rollers RL may transfer the substrate carrier CR. Specifically, the substrate carrier CR inserted into the chamber CB through the inlet port EN may be transferred along the first direction D1 through the transfer rollers RL, and may be taken out of the chamber CB through the outlet port EX.

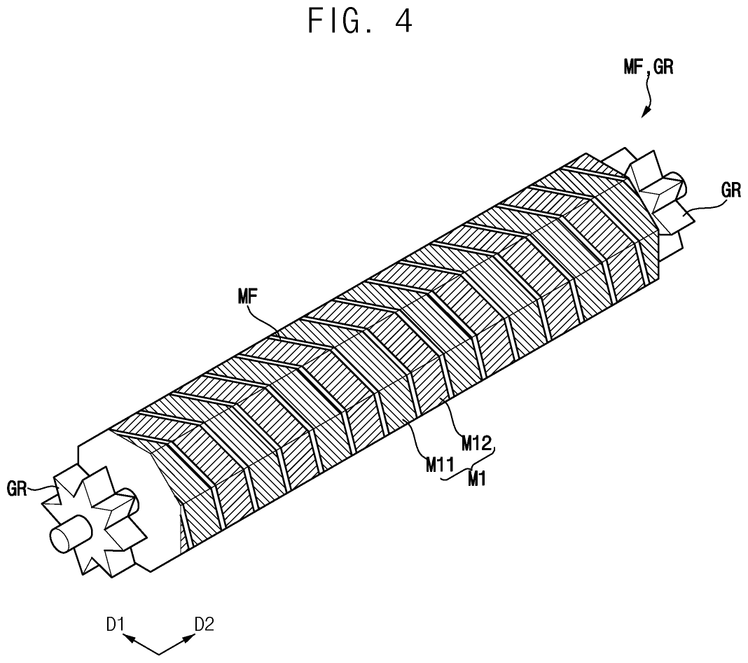

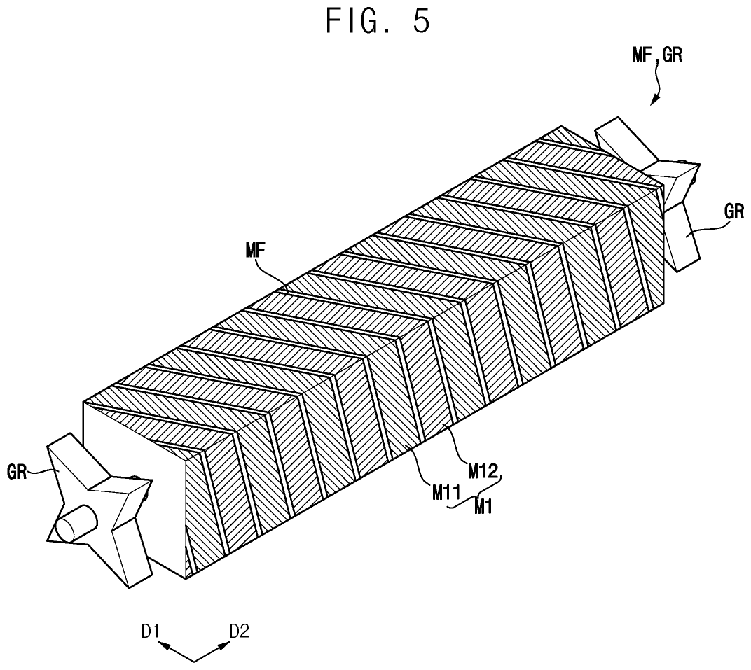

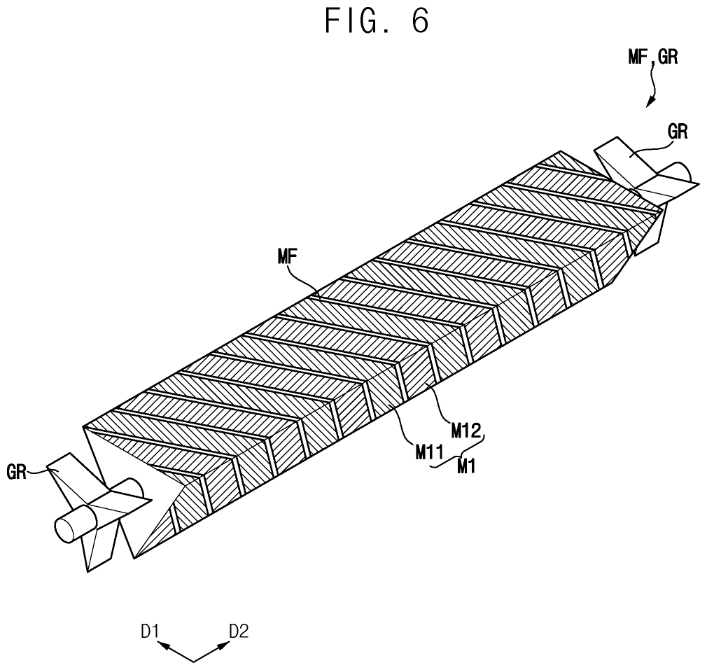

FIG. 4 is a perspective view illustrating another embodiment of FIG. 3. FIG. 5 is a perspective view illustrating still another embodiment of FIG. 3. FIG. 6 is a perspective view illustrating still another embodiment of FIG. 3.

Hereinafter, descriptions overlapping those of the magnet filter MF and the gear GR described with reference to FIGS. 1, 2 and 3 will be omitted or simplified.

In an embodiment and referring to FIGS. 2, 4, 5 and 6, the filter FP may include the magnet filter MF and the gear GR.

In an embodiment, the magnet filter MF may include the first magnet M1 forming the outer surface of the magnet filter MF. The first magnet M1 may include the (1-1)th magnet M11 and the (1-2)th magnet M12 having different polarities. The (1-1)th magnet M11 and the (1-2)th magnet M12 may have a spiral shape, and may be alternately arranged. That is, each of the (1-1)th magnet M11 and the (1-2)th magnet M12 may have a spiral shape surrounding the outer surface of the magnet filter MF.

In an embodiment, the magnet filter MF may have a polygonal column shape including n side surfaces. The gear GR may be disposed at both ends of the magnet filter MF, and may include n teeth. That is, the number of side surfaces included in the magnet filter MF and the number of teeth included in the gear GR may be the same.

For example, in an embodiment, the magnet filter MF may have an octagonal column shape including eight side surfaces. At this time, the gear GR may include eight teeth (see FIG. 4).

For another example, in an embodiment, the magnet filter MF may have a quadrangular column shape including four side surfaces. At this time, the gear GR may include four teeth (see FIG. 5).

For still another example, in an embodiment, the magnet filter MF may have a triangular column shape including three side surfaces. At this time, the gear GR may include three teeth (see FIG. 6).

In an embodiment, the gear GR may allow the magnet filter MF to rotate one side surface at a time. That is, as the magnet filter MF includes n side surfaces and the gear GR includes n teeth, the magnet filter MF may be rotatable by 360/n° about the axis that is parallel to the second direction D2.

Although FIGS. 3, 4, 5 and 6 illustrate that the magnet filter MF includes 3, 4, 6 or 8 side surfaces and the gear GR includes 3, 4, 6 or 8 teeth, the invention is not limited thereto. Alternatively, in an embodiment, the magnet filter MF may include 5, 7, or 9 or more side surfaces and the gear GR may also include 5, 7, or 9 or more teeth.

In the substrate treating apparatus 10 according to an embodiment, the magnet filter MF may have a polygonal column shape including n side surfaces, and may be rotatable. As the magnet filter MF is rotated, the magnet filter MF may collect metal foreign substances generated in the process using each side surface. Accordingly, an ability of the magnet filter MF to collect metal foreign substances may be increased, and a cleaning cycle of the magnet filter MF may be relatively long.

In addition, in an embodiment, since the magnet filter MF may be rotated by the magnetic force between the first magnet M1 of the magnet filter MF and the second magnet M2 of the substrate carrier CR, the chamber CB may be maintained in a vacuum state. That is, since conversion of the internal state of the chamber CB is not required, process efficiency may be improved.

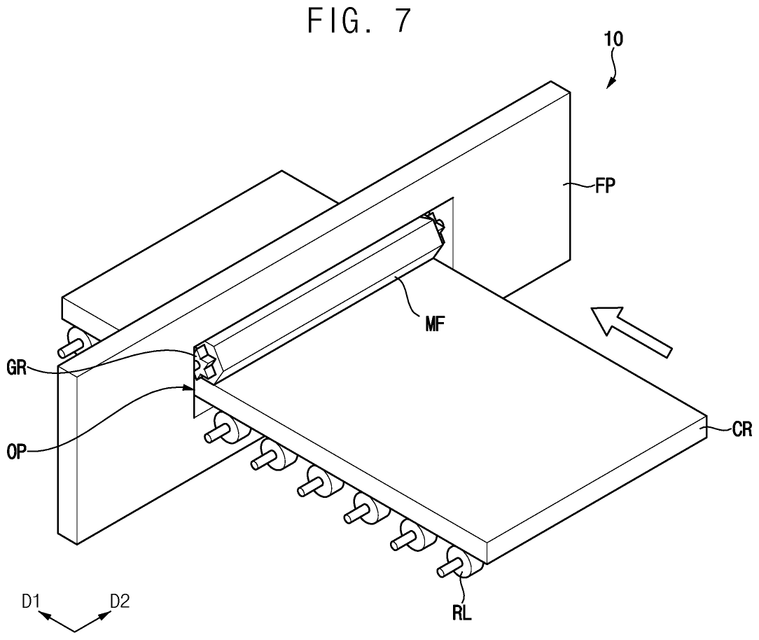

FIG. 7 is a perspective view illustrating another embodiment of FIG. 2.

Hereinafter, descriptions overlapping those of the substrate treating apparatus 10 described with reference to FIGS. 1, 2 and 3 will be omitted or simplified.

In an embodiment and referring to FIGS. 1 and 7, the substrate treating apparatus 10 may include the chamber CB, the filter FP, the substrate carrier CR and the transfer rollers RL.

In an embodiment, the substrate carrier CR may be movable in the first direction D1. In the chamber CB, the substrate carrier CR may pass through the filter FP through the opening OP.

In an embodiment, the filter FP may include the magnet filter MF and the gear GR. The magnet filter MF may include a magnet. Accordingly, the magnet filter MF may collect metal foreign substances generated in the process of treating the target substrate.

In an embodiment, the magnet filter MF may have a polygonal column shape including n side surfaces. The magnet filter MF may be rotatable by one side surface about the axis which is parallel to the second direction D2. That is, the magnet filter MF may be rotatable by 360/n° about the axis which is parallel to the second direction D2.

In an embodiment, the gear GR may be disposed at both ends of the magnet filter MF, respectively. The gear GR may include n teeth. That is, the number of side surfaces included in the magnet filter MF and the number of teeth included in the gear GR may be the same. Accordingly, the gear GR may allow the magnet filter MF to rotate in increments of one side surface at a time.

In an embodiment, unlike the substrate carrier CR described with reference to FIG. 2, the substrate carrier CR described with reference to FIG. 7 may not include a magnet.

In an embodiment, the magnet filter MF may be manually rotatable. Specifically, when metal foreign substances are accumulated on one side surface of the magnet filter MF, the magnet filter MF may be manually rotated to another side surface adjacent to the one side surface. That is, when rotation of the magnet filter MF is required, the magnet filter MF may be manually rotated by 360/n°. In this case, since the magnet filter MF may be manually rotated, the inside of the chamber CB may be maintained in an atmospheric pressure state while the magnet filter MF is rotated. That is, for rotation of the magnet filter MF, the internal state of the chamber CB may be converted from a vacuum state to an atmospheric pressure state.

In another embodiment, the substrate treating apparatus 10 may include a controller disposed outside the chamber CB. The controller may be connected to the magnet filter MF, and may rotate the magnet filter MF. That is, when metal foreign substances are accumulated on the one side surface of the magnet filter MF, the controller may rotate the magnet filter MF to the other side surface. That is, when rotation of the magnet filter MF is required, the magnet filter MF may be rotated by 360/n° by the controller.

In still another embodiment, the magnet filter MF may include a zero-electronic magnet. In this case, power may be supplied to the magnet filter MF. When metal foreign substances are accumulated on the one side surface of the magnet filter MF, power may be supplied to the magnet filter MF to rotate the magnet filter MF to the other side surface. That is, when rotation of the magnet filter MF is required, the magnet filter MF may be rotated by 360/n° by electric power.

In the substrate treating apparatus 10 according to an embodiment, the magnet filter MF may have a polygonal column shape including n side surfaces, and may be rotatable. As the magnet filter MF is rotated, the magnet filter MF may collect metal foreign substances generated in the process using each side surface. Accordingly, since an ability of the magnet filter MF to collect metal foreign substances is increased and a cleaning cycle of the magnet filter MF may be relatively long, process efficiency may be improved.

The invention can be applied to a manufacturing process of various display devices. For example, the invention is applicable to a manufacturing process of various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims. Moreover, the embodiments or parts of the embodiments may be combined in whole or in part without departing from the scope of the invention.

What is claimed is:

1. A substrate treating apparatus comprising:
a chamber defining a chamber cavity;
a substrate carrier movable in a first direction inside the chamber cavity; and
a filter disposed inside the chamber cavity, defining an opening through which the substrate carrier passes, and including a magnet filter disposed in the opening and being rotatable.

2. The substrate treating apparatus of claim 1, wherein the magnet filter extends in a second direction intersecting the first direction, and has a polygonal column shape including n side surfaces, wherein where n is a natural number greater than or equal to three.

3. The substrate treating apparatus of claim 2, wherein the magnet filter is rotatable by 360/n° around an axis that is directed parallel to the second direction, wherein where n is a natural number equal to or greater than three.

4. The substrate treating apparatus of claim 1, wherein the filter includes a gear disposed at a first end and a second end of the magnet filter.

5. The substrate treating apparatus of claim 1, wherein the magnet filter includes a first magnet forming an outer surface.

6. The substrate treating apparatus of claim 5, wherein the first magnet includes a south pole and a north pole alternately arranged.

7. The substrate treating apparatus of claim 5, wherein the substrate carrier includes a second magnet disposed on one surface located adjacent to the magnet filter.

8. The substrate treating apparatus of claim 7, wherein the second magnet includes a south pole and a north pole alternately arranged.

9. The substrate treating apparatus of claim 7, wherein the magnet filter is rotated by a magnetic force between the first magnet and the second magnet.

10. A method of treating a substrate, the method comprising:
inserting a substrate carrier into a chamber cavity;
passing the substrate carrier through an opening defined in a filter disposed inside the chamber cavity; and
rotating a magnet filter disposed in the opening.

11. The method of claim 10, wherein the magnet filter extends in one direction, and has a polygonal column shape including n side surfaces, wherein n is a natural number greater than or equal three.

12. The method of claim 11, wherein
the magnet filter is rotatable by 360/n° around an axis that is directed parallel to the one direction.

13. The method of claim 10, wherein passing the substrate carrier, includes
the magnet filter collecting metal foreign substances disposed on the substrate carrier.

14. The method of claim 10, wherein rotating a magnet filter includes maintaining the chamber cavity in a vacuum state.

15. The method of claim 10, wherein the magnet filter includes a first magnet forming an outer surface.

16. The method of claim 15, wherein the substrate carrier includes a second magnet disposed on one surface located adjacent to the magnet filter.

17. The method of claim 16, wherein each of the first magnet and the second magnet includes a south pole and a north pole alternately arranged.

18. The method of claim 16, wherein rotating a magnet filter includes,
rotating the magnet filter by a magnetic force located between the first magnet and the second magnet.

19. The method of claim 10, wherein rotating a magnet filter includes,
maintaining an atmospheric pressure state within the chamber cavity.

20. The method of claim 10, wherein the filter includes a gear disposed at a first end and a second end of the magnet filter.
